(19) United States
(12) Patent Application Publication
(10) Pub. No.: US 2025/0308608 A1
(43) Pub. Date: Oct. 2, 2025

(54) ULTRA-LOW POWER, HIGH SPEED POLY FUSE EPROM

(71) Applicant: TEXAS INSTRUMENTS INCORPORATED, Dallas, TX (US)

(72) Inventors: Likhita Chandrashekara, Bangalore (IN); Yash Didhe, Dombivli (IN); Rajat Chauhan, Bangalore (IN); Devraj Rajagopal, Bangalore (IN)

(21) Appl. No.: 19/233,174

(22) Filed: Jun. 10, 2025

Related U.S. Application Data
(63) Continuation of application No. 18/114,449, filed on Feb. 27, 2023, now Pat. No. 12,327,598.
(60) Provisional application No. 63/400,501, filed on Aug. 24, 2022.

(51) Int. Cl. G11C 17/18; G11C 17/16; H01L 23/525; H10B 20/25

(52) U.S. Cl. CPC G11C 17/18; G11C 17/16; H01L 23/5256; H10B 20/25

(57) ABSTRACT

An integrated circuit includes a memory cell that includes a first and second cross-coupled inverters, an output of the first inverter connected to an input of the second inverter, and an output of the second inverter connected to an input of the first inverter. A resistor and a first switch are between a power rail and a power terminal of the first inverter, a fuse and a second switch are between the power rail and a power terminal of the second inverter. The first and second switches are configured to conduct during a first phase of a control signal. A third switch is between the output of the first inverter and a reference rail and a fourth switch is between the output of the second inverter and the reference rail. The third and fourth switches are configured to conduct during a second phase of the control signal.

### CROSS REFERENCE TO RELATED APPLICATIONS

This application claims the benefit of U.S. provisional application Ser. No. 63/400,501 filed Aug. 24, 2022 which is incorporated herein by reference in its entirety. This application is a continuation of U.S. Pat. No. 12,327,598.

### FIELD

This disclosure relates to the field of semiconductor devices, and more particularly, but not exclusively, to memory cells.

### BACKGROUND

Electrically-programmable memory cells enjoy uses in many contexts, including trimming various analog circuits to account for manufacturing variation. Such cells consume valuable space on an IC die, and may contribute to reliability issues.

### SUMMARY

One example includes an integrated circuit with a memory cell that includes a first and second cross-coupled inverters, an output of the first inverter connected to an input of the second inverter by a first circuit node, and an output of the second inverter connected to an input of the first inverter by a second circuit node. The integrated circuit also includes a first circuit path from a higher voltage rail to a power terminal of the first inverter, and a second circuit path from the higher voltage rail to a power terminal of the second inverter. The integrated circuit also includes a first switch in the first circuit path and a second switch in the second circuit path, the first and second switches configured to conduct during a first phase of a control signal. The integrated circuit also includes a third switch between the first circuit node and a lower voltage rail and a fourth switch between the second circuit node and the lower voltage rail, the third and fourth switches configured to conduct during a second phase of the control signal. The integrated circuit also includes a resistor in the first circuit path and a fuse in the second circuit path.

Another example provides a method of operating a memory cell. A control signal is switched from a first state to a second state. A first switch and a second switch are closed responsive to the second state. The first switch is coupled between a fuse and a first power terminal of a first inverter. The second switch is coupled between a resistor and a second power terminal of a second inverter. The fuse and the resistor are coupled to a first supply rail. Third and Fourth switches are opened responsive to the second state. The third switch is coupled between an output of the first inverter and a second supply rail. The fourth switch is coupled between an output of the second inverter and the second supply rail. The output of the first inverter is also coupled to an input of the second inverter. The output of the second inverter is also coupled to an input of the first inverter. The value of the output of the first inverter is read responsive to the second state after the output of the first inverter stabilizes.

Yet another example provides a method of fabricating an integrated circuit. First and second cross-coupled inverters are formed over a semiconductor substrate, an output of the first inverter is connected to an input of the second inverter by a first circuit node and an output of the second inverter is connected to the input of the first inverter by a second circuit node. A first switch is formed over the semiconductor substrate and connected in a first circuit path from a power rail to a power terminal of the first inverter. The first switch is configured to conduct during a first phase of a control signal. A second switch is formed over the semiconductor substrate and connected in a second circuit path from the power rail to a power terminal of the second inverter. The second switch is configured to conduct during the first phase of the control signal. A third switch is formed over the semiconductor substrate and connected between the first circuit node and a reference rail. The third switch is configured to conduct during a second phase of the control signal. A fourth switch is formed over the semiconductor substrate and connected between the second circuit node and the reference rail. The fourth switch is configured to conduct during the second phase of the control signal. A resistor is formed over the semiconductor substrate and connected between the power rail and the first switch in the first circuit path. A fuse is formed over the semiconductor substrate and connected between the power rail and the second switch in the second circuit path.

### BRIEF DESCRIPTION OF THE VIEWS OF THE DRAWINGS

FIG. 1 illustrates a fuse memory cell circuit according to the disclosure;

FIG. 2 illustrates a fuse memory cell circuit such as that shown in FIG. 1 with additional components;

FIG. 3 presents a timing diagram illustrating aspects of operation of the fused memory cell circuits of FIGS. 1 and 2.

FIG. 4 illustrates a fuse memory cell circuit such as that shown in FIG. 2 including current sinks connected to a fuse and a reference resistor;

FIG. 5 illustrates an implementation of a fused memory cell circuit such as that shown in FIG. 2 on a semiconductor die;

FIG. 6 illustrates an array of fused memory cell circuits such as that shown in FIG. 5; and

FIG. 7 illustrates a method of forming an integrated circuit according to various examples.

### DETAILED DESCRIPTION

The present disclosure is described with reference to the attached figures. The figures may not be drawn to scale and they are provided merely to illustrate the disclosure. Several aspects of the disclosure are described below with reference to example applications for illustration, in which like features correspond to like reference numbers. It should be understood that numerous specific details, relationships, and methods are set forth to provide an understanding of the disclosure. The present disclosure is not limited by the illustrated ordering of acts or events, as some acts may occur in different orders and/or concurrently with other acts or events. Furthermore, not all illustrated acts or events may be required to implement a methodology in accordance with the present disclosure.

This application discloses various methods and devices that may be beneficially applied to integrated circuits (ICs), such as those including electrically programmable fuse memory cells, e.g. by reducing static current and providing a short read time. While such embodiments may be expected to provide improvements such as reducing overall IC power requirements, no particular result is a requirement of the described invention(s) unless explicitly recited in a particular claim.

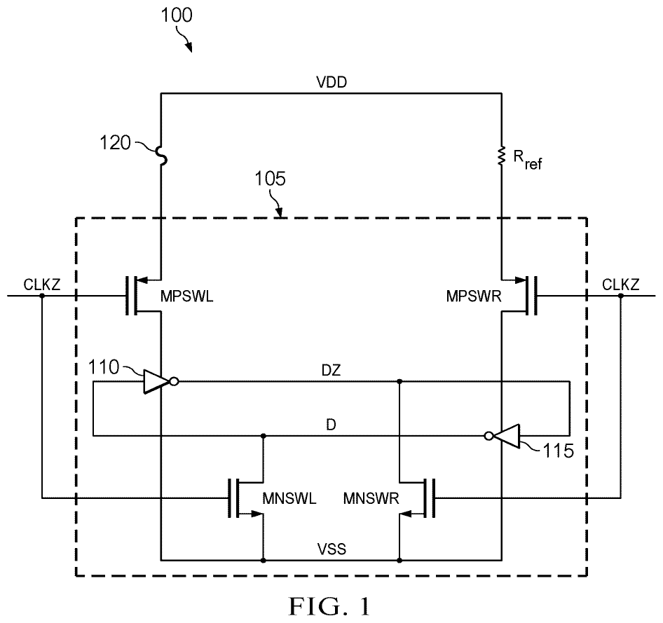

Referring to FIG. 1, an electrically programmable memory cell 100 is schematically illustrated. The memory cell 100 includes a sense amplifier 105 that includes a latch having a first inverter 110 and a second inverter 115. The inverters 110, 115 are cross-coupled in a manner that may store a bit-value in a quasi-static fashion. For convenience of description the output of the inverter 115 is designated as the “D node”, and the output of the inverter 110 is designated as the inverse of the D node, or the “DZ node”. The inverters 110, 115 are configured with other components of the memory cell 100 in left-right symmetric fashion. A “left-hand leg” of the memory cell 100 includes a PMOS transistor MPSWL with a source connected to a fuse 120 and a drain connected to a positive power terminal of the inverter 110. An NMOS transistor MNSWL has a drain connected to the D node and a source connected to a lower power rail designated VSS. Similarly, a “right-hand leg” includes a PMOS transistor MPSWR with a source connected to R_{ref} and a drain connected to a positive power terminal of the inverter 115. An NMOS transistor MNSWR has a drain connected to the DZ node and a source connected to VSS. During the positive phase of a CLKZ signal, the transistor MNSWL conductively connects the D node to VSS, and the transistor MNSWR conductively connects the DZ node to the VSS. During the negative phase of CLKZ, the transistor MPSWL conductively connects the positive power terminal of the inverter 110 to the fuse 120, and the transistor MPSWR conductively connects the positive power terminal of the inverter 115 to R_{ref}.

Negative power terminals of the inverters 110 and 115 are connected to the lower power rail in an unswitched fashion. Conversely, the inverter 110 is connected to an upper power rail, designated VDD, via the transistor MPSWL and the fuse 120, and the inverter 115 is connected to VDD via the transistor MPSWR and V_{ref}. The transistor MPSWL is directly connected to the first terminal of a fuse 120, and the MPSWR is directly connected to a first terminal of the reference resistor R_{ref}. A second terminal of the fuse 120 and a second terminal of R_{ref} are both connected to VDD.

The fuse 120 may be formed from any material that can be patterned to form a current path that may be selectively broken to produce a high-resistance state between the first and second fuse terminals. In various examples, and as described without implied limitation, the fuse 120 is formed from polysilicon. In various examples the fuse 120 has an “hourglass” or “dog bone” shape, in which wide terminal portions with relatively low resistance are initially connected by a narrow conductive path having an initial resistance. A sufficiently high current, producing a commensurately high current density, may damage a portion of the narrow conductive path resulting in a programmed resistance that is typically much larger than the initial resistance. For example, the fuse 120 may have a resistance R_{fuse} that has an initial, unprogrammed value of about 100Ω, and a programmed value greater than 50 kΩ.

The reference resistor R_{ref} has a resistance that is greater than the unprogrammed resistance of the fuse 120 and less than the programmed resistance of the fuse 120. In one example, R_{ref} may be about one-half of the minimum expected value of R_{fuse} in the programmed state, for example 25 kΩ. In various examples, R_{ref} is significantly greater, e.g. >100×, than the unprogrammed resistance of the fuse 120.

In a non-read, or quiescent state, CLK is unasserted, resulting in MNSWL and MNSWR being switched on and pulling the D and DZ nodes to VSS. In a read state CLK is asserted, allowing D and DZ to settle to an active state. This condition results in insignificant power consumption by the memory cell 100. The value of the D node in the active state is determined by the relative resistance of R_{fuse} and R_{ref}. As described in greater detail below, if R_{fuse}<R_{ref}, e.g. in an unprogrammed state, the D node will settle to an unasserted value, e.g. a digital “0” or FALSE state, and the DZ node will settle to an asserted value, e.g. a digital “1” or TRUE state. Conversely, if R_{fuse}>R_{ref}, e.g. in an programmed state, the D node will settle to a TRUE state, and the DZ node will settle to a FALSE state. After settling into the active state, insignificant power is consumed by the memory cell 100.

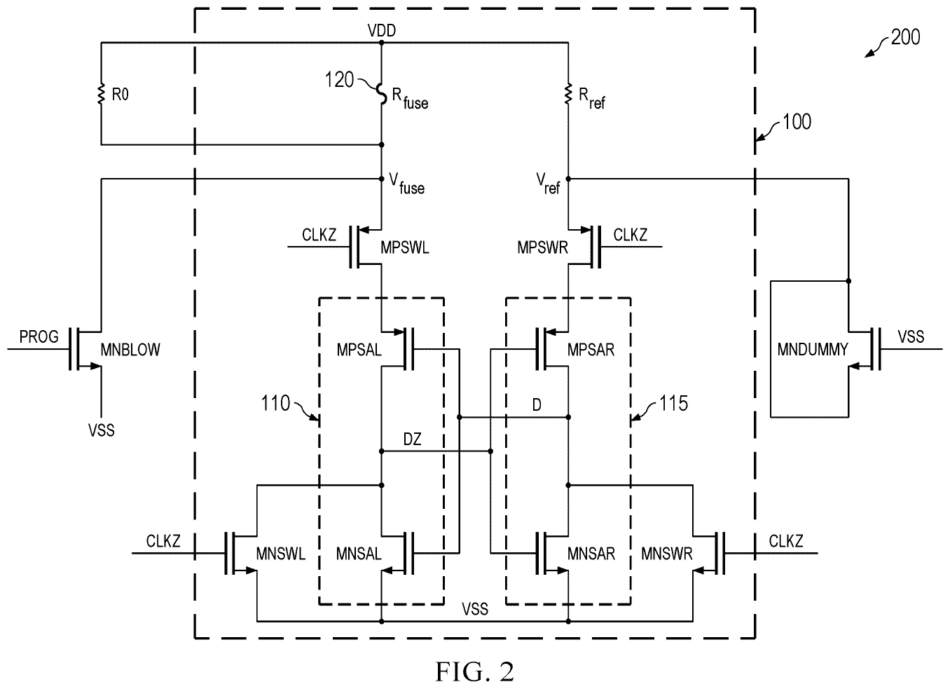

FIG. 2 illustrates an example of a memory cell 200 in which the inverter 110 is implemented by a PMOS transistor MPSAL and an NMOS transistor MNSAL, and the inverter 115 is implemented by a PMOS transistor MPSAR and an NMOS transistor MNSAR. MPSAL and MNSAL are connected at a first output node that serves as the DZ node, and MPSAR and MNSAR are connected at a second output node that serves as the D node. Gate terminals of MPSAL and MNSAL are connected at a first input node connected to the D node, and gate terminals of MPSAR and MNSAR are connected at a second input node connected to the DZ node

As described previously, in a quiescent state (e.g. CLK=FALSE and CLKZ=TRUE) the transistors MNSWL and MNSWR are switched on, holding the D and DZ node values to VSS. In a read state (e.g. CLK=TRUE and CLKZ=FALSE), MNSWL and MNSWR are switched off and MPSWL and MPSWR are switched on. Immediately following the transition from the quiescent state to the active state, MPSAL and MPSAR are switched on and MNSAL and MNSAR are switched off due to the immediately preceding VSS state of the D and DZ nodes. The state at which the D and DZ nodes settle is determined by a race between the left-hand leg and the right-hand leg. The combined resistance and capacitance of the components in the left-hand leg result in a first time constant τ_{L} that determines the rate at which the voltage of the DZ node increases from VSS, and the combined resistance and capacitance of the components in the right-hand leg result in a second time constant τ_{R} that determines the rate at which the voltage of the D node increases from VSS. If τ_{L}<τ_{R} (unprogrammed state) DZ increases to a value sufficient to switch on MNSAR before D can increase to a value sufficient to switch on MNSAL, and the D and DZ nodes respectively settle to values of 0 and 1. On the other hand, if τ_{L}>τ_{R} (programmed state) D increases to a value sufficient to switch on MNSAL before DZ can increase to a value sufficient to switch on MNSAR, and the nodes D and DZ nodes respectively settle to values of 1 and 0.

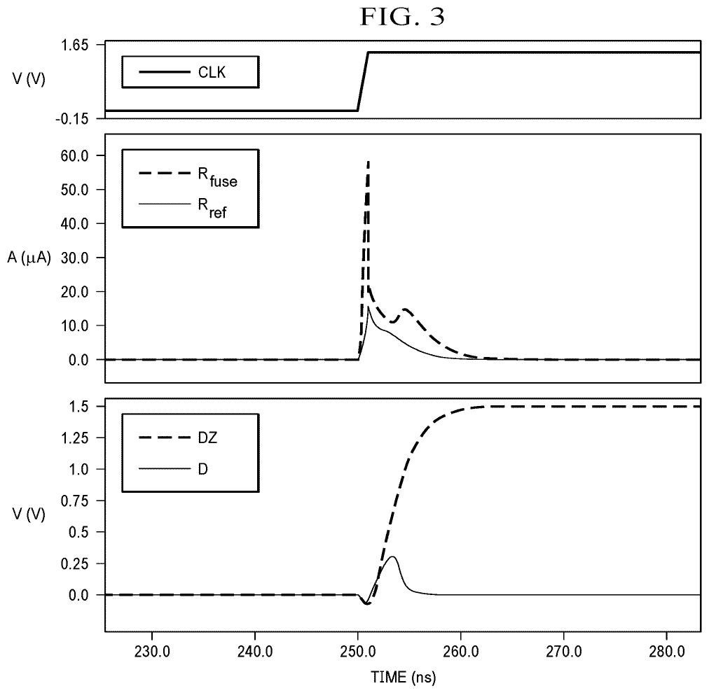

Read operation is exemplified in FIG. 3, which shows simulated voltage and current values versus time t at various nodes of the memory cell 100 for the example of R_{fuse}=100Ω (unprogrammed) and R_{ref}=25 kΩ. Prior to t=250 ns, CLK is unasserted (CLKZ is asserted), the current through the fuse 120 and R_{ref} are both zero, and the voltage at the D and DZ nodes is zero. CLK is asserted at t=250 ns, which results in a peak current of about 55 μA through the fuse 120 and a peak current of about 15 μA through the reference resistor R_{ref}. Initially the voltage at the D and DZ nodes increases about a same rate, but within 2-3 ns the voltage at the DZ node overtakes the voltage at the D node and the state of the memory cell 100 settles in the unprogrammed state. The current through the fuse 120 and R_{ref} return to zero when the state of the memory cell 100 settles. Thus the static current is seen to be very low, e.g. ≤75 nA, and the read time is very short, e.g. <17 ns.

It is noted the voltages shown in FIG. 3 are only one example provided without implied limitation. In this example the circuit uses 5 V transistors and is operating between 0.9 V and 5.5 V, where 0.9 V is determined by the threshold voltage of the transistors and 5.5 V is determined as a reliable operating limit of a 5 V transistor. The voltage range of operation can be extended, e.g. by using low threshold-voltage (LVT) devices in some other examples.

Returning to FIG. 2, in various examples the transistors MPSWL and MPSWR are matched, e.g. have about a same (within manufacturing tolerance) resistance and capacitance. For example, each of these transistors may have a same gate length (or channel length) and a same gate width (or drive current). Similarly, in various examples MPSAL and MPSAR are matched, and MNSAL and MNSAR are matched. In some examples, all of the transistors in the memory cell 100 are closely spaced on a semiconductor substrate such that manufacturing variation is negligible between matched transistors.

Other components of the memory cell 200 include transistors MNBLOW and MNDUMMY. In a programming operation, MNBLOW is switched by an asserted PROG signal and acts to sink current through the fuse 120 if in the unprogrammed state. The drive current capacity of MNBLOW is selected to support a sufficient current to damage the narrow conductive path of the fuse 120, increasing the resistance from the unprogrammed value to the programmed value. The connection of MNBLOW to the fuse 120 terminal may increase the capacitance associated with the left-hand leg of the memory cell 100, and without compensation result in altering the timing of operation during the previously described settling period. In some examples, the MNDUMMY is a dummy transistor matched to the MNBLOW transistor to provide such compensation. In such examples the source and drain of MNDUMMY are connected so this transistor provides no active electrical function.

In an additional example, a shunt resistor R0 is connected to the terminals of the fuse 120 to inhibit growth of a low-resistance path between the terminals after the fuse 120 is blown. Such regrowth may result from the electric field between the terminals in the absence of the shunt resistor. In various examples R0 has a resistance at least twice that of a predetermined minimum resistance of the fuse 120 in the programmed state. Space permitting, it may be desirable that R0 has a resistance at least ten times that of the predetermined minimum resistance of the fuse 120 in the programmed state, e.g. about 500 kΩ.

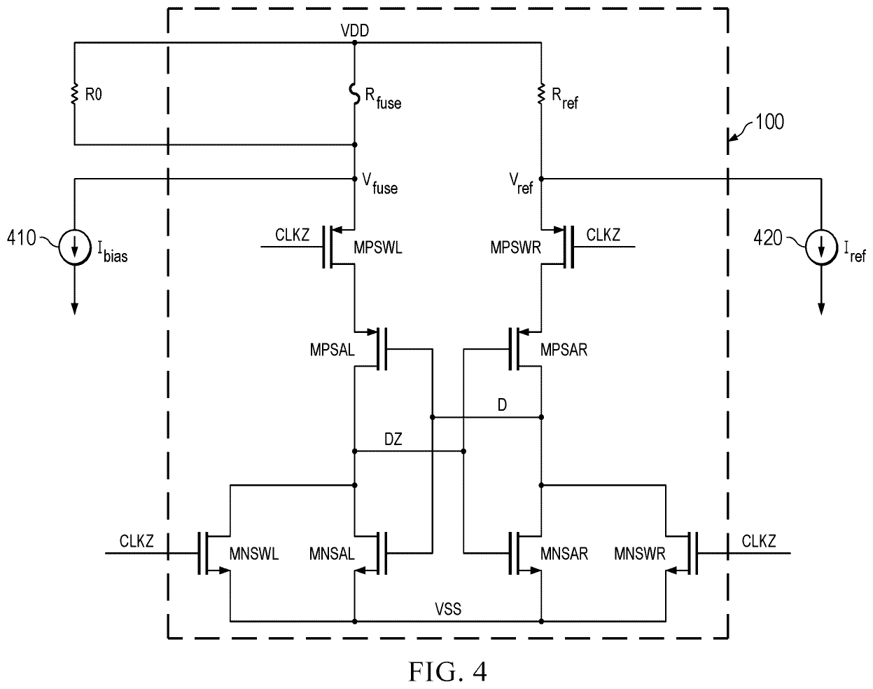

FIG. 4 illustrates the memory cell 100 in an example in which a first bias current sink 410 is connected to the fuse 120 and a second bias current sink 420 is connected to R_{ref}. This configuration may be used to test the operating margin of the memory cell 100 after programming the fuse 120. In an example, a minimum desired resistance of the fuse 120 after programming may be predetermined to be 50 kΩ. In the example that R_{ref} has a value of 25 kΩ, the second bias current sink 420 may be configured to sink through R_{ref} a bias current I_{ref} that is two times (50 kΩ/25 kΩ) a bias current I_{bias} drawn by the first bias current sink 410. This configuration may be used to test the operating margin of the memory cell 100 after programming the fuse 120. In another example, the minimum desired resistance of the fuse 120 after programming may be predetermined to be 100 kΩ, in which case I_{ref} may be four times I_{bias}. The configuration of I_{ref} as a multiple of I_{bias} allows R_{ref} to be made smaller than the minimum desired resistance of the fuse in the programmed state, reducing the die area needed to implement R_{ref}. As R_{ref} is made smaller, I_{ref} may be increased to produce the desired voltage drop across R_{ref}, increasing the size of the components implementing the current sink 420 and/or interconnections to R_{ref}, or even risking damaging R_{ref}. Thus in various examples a minimum ratio of I_{ref} to I_{bias} may be 2 to limit the size of such components.

When the CLK is unasserted and the current sinks 410, 420 are operated, a voltage V_{fuse} is produced at the node between the fuse 120 and the transistor MPSWL. Similarly, a voltage V_{ref} is produced at the node between R_{ref} and the transistor MPSWR. Under example conditions in which R_{ref} has a value of 25 kΩ and I_{ref}=4*I_{fuse}, if V_{fuse}<V_{ref} then R_{fuse} can be inferred to be greater than 100 kΩ. Conversely, if V_{fuse}>V_{ref} then R_{fuse} can be inferred to be less than the predetermined minimum of 100 kΩ. In response to this condition, which may fail to meet a desired margin specification, the IC in which the memory cell 100 is implemented may be scrapped.

The described principle can be generalized such that the second bias current sink 420 is configured such that to I_{ref} is n times greater than I_{bias}. V_{fuse} will equal V_{ref} when R_{fuse}=n*R_{ref}, or n*25 kΩ in the case that R_{ref}=25 kΩ. Furthermore, in general the ratio I_{ref}/I_{bias} need not be an integer value.

The current sinks 410, 420 may be provided by current sinks that are integrated into the IC, or may be provided external to the IC, such as in a multi-probe test configuration. When integrated into the IC, the current sinks 410, 420 provide the ability to determine if the resistance of the fuse 120 meets the predetermined operating margin independently of an external tester, including after deployment in an electronic system. On the other hand, if one or both of the current sinks 410, 420 are provided externally, then I_{bias} and/or I_{ref} may be varied as desired to determine an arbitrary operating margin ratio, and multiple test measurements may be performed, e.g. to determine the actual value of R_{fuse}.

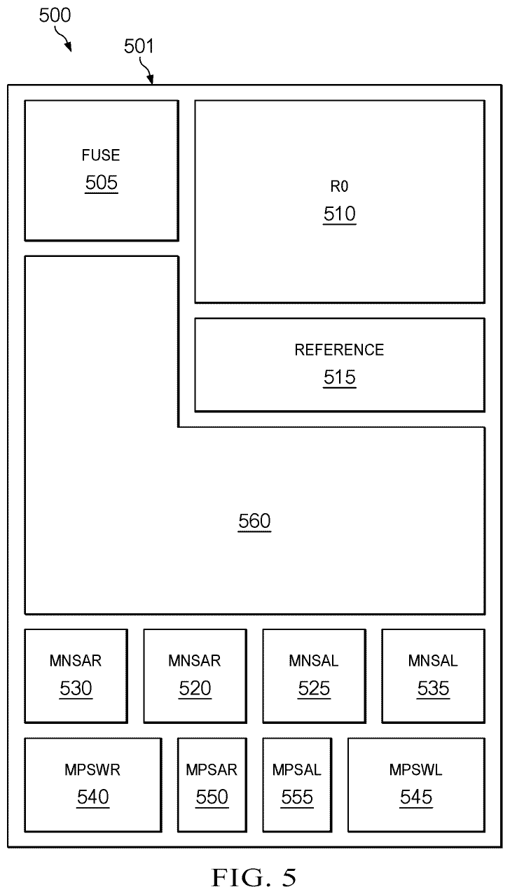

FIG. 5 illustrates a memory cell 500 as implemented on a silicon substrate 501 in various examples. Various designations of features of the memory cell 500 may correspond to features previously described. The memory cell 500 includes a fuse structure 505 and a shunt resistor 510, respectively exemplified by the fuse 120 and the shunt resistor R0 of FIG. 2. A reference resistor 515, exemplified by the resistor R_{ref} of FIG. 2, is located below the shunt resistor 510. The fuse structure 505 may be formed at least in part in a polysilicon layer or a metal interconnect layer over the substrate 501. The resistors 510, 515 may be formed in a polysilicon layer over the substrate 501, or in a diffusion region extending into the substrate 501. Transistors 520 and 525 exemplify the transistors MNSAR and MNSAL of FIG. 2; transistors 530 and 535 exemplify the transistors MNSAR and MNSAL of FIG. 2; transistors 540 and 545 exemplify the transistors MPSWR and MPSWL of FIG. 2; and transistors 550 and 555 exemplify the transistors MPSAR and MPSAL of FIG. 2. Each of the transistors 520, 525, 530, 535, 540, 545, 550 and 555 may be formed over and extending into the substrate 501 by any current or future-discovered methods. In various examples, Transistors 520 and 525 are matched, transistors 530 and 535 are matched, transistors 540 and 545 are matched, and/or transistors 550 and 555 are matched. Logic functions 560 related to other operating characteristics of the memory cell 500 are located between the fuse structure 505 and resistors 510, 515 and the transistors 520 . . . 555.

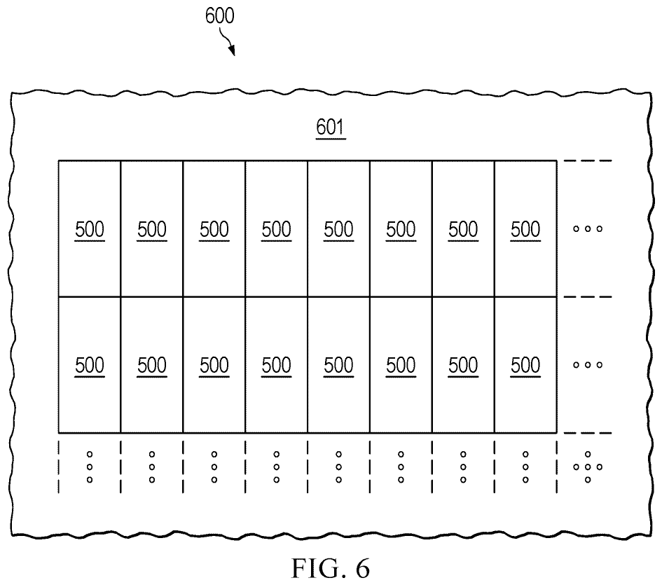

FIG. 6 illustrates an array 600 of the memory cells 500 as may be formed in an integrated circuit. Any number of the memory cells 500 may be formed over and extending into a semiconductor substrate 601. In the illustrated example, a number, e.g. 16, of the memory cells 500 are formed as a two-dimensional array. In other examples, an array of the memory cells 500 may be one-dimensional, or may be located arbitrarily within an integrated circuit design.

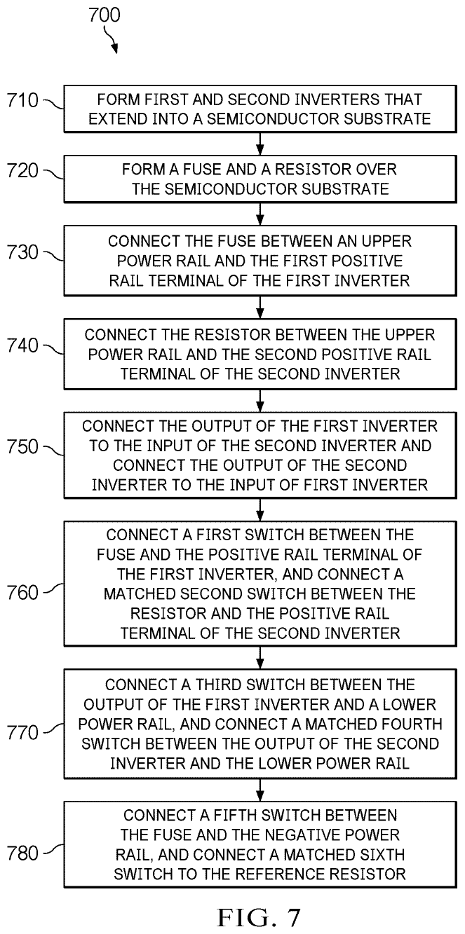

FIG. 7 describes a method 700 of forming an integrated circuit as described in the present disclosure. In a step 710 first and second inverters are formed extending into a semiconductor substrate. The first inverter has a first positive power terminal, a first output at a first output node, and a first input node. The second inverter has a second positive power terminal, a second output at a second output node, and a second input node.

In a step 720 a fuse and a resistor are formed over the semiconductor substrate.

In a step 730 the fuse is connected between an upper power rail and the first positive power terminal of the first inverter.

In a step 740 the resistor is connected between the upper power rail and the second positive power terminal of the second inverter.

In a step 750 the output node of the first inverter is connected to the input node of the second inverter and the output node of the second inverter is connected to the input node of first inverter.

In a step 760 a first switch is connected between the fuse and the positive power terminal of the first inverter, and a second switch is connected between the resistor and the positive power terminal of the second inverter.

In a step 770 a third switch is connected between the output node of the first inverter and a lower power rail, and a fourth switch is connected between the output node of the second inverter and the lower power rail. The first and second switches are configured to provide low resistance during a first phase of a control signal, and the third and fourth switches are configured to provide low resistance during a second phase of the control signal.

In a step 780 a fifth switch is connected between the fuse and the negative power rail, and a sixth switch is connected to the reference resistor. The fifth switch is configured to provide low resistance in response to a programming signal.

While various embodiments of the present disclosure have been described above, it should be understood that they have been presented by way of example only and not limitation. Numerous changes to the disclosed embodiments can be made in accordance with the disclosure herein without departing from the spirit or scope of the disclosure. Thus, the breadth and scope of the present invention should not be limited by any of the above described embodiments. Rather, the scope of the disclosure should be defined in accordance with the following claims and their equivalents.

1. An integrated circuit, comprising:
a memory cell circuit including first and second cross-coupled inverters, an output of the first inverter connected to an input of the second inverter by a first circuit node and an output of the second inverter connected to an input of the first inverter by a second circuit node;
a first circuit path from a higher voltage rail to a power terminal of the first inverter, and a second circuit path from the higher voltage rail to a power terminal of the second inverter;
a first switch in the first circuit path and a second switch in the second circuit path, the first and second switches configured to conduct during a first phase of a control signal;
a third switch between the first circuit node and a lower voltage rail and a fourth switch between the second circuit node and the lower voltage rail, the third and fourth switches configured to conduct during a second phase of the control signal;
a resistor in the first circuit path; and
a fuse in the second circuit path.

2. The integrated circuit of claim 1, wherein the memory cell circuit is one of a plurality of memory cell circuits.

3. The integrated circuit of claim 2, wherein the plurality of memory cell circuits is arranged in a two-dimensional array.

4. The integrated circuit of claim 1, wherein the first switch and the second switch include first matched transistors, and the third switch and the fourth switch include second matched transistors.

5. The integrated circuit of claim 1, wherein the first inverter has a first NMOS transistor matched to a second NMOS transistor of the second inverter, and the first inverter has a first PMOS transistor matched to a second PMOS transistor of the second inverter.

6. The integrated circuit of claim 1, further comprising a second resistor coupled in parallel with the fuse in the second circuit path.

7. The integrated circuit of claim 1, further comprising a fifth switch connected between the fuse and the lower voltage rail and configured to cause current to flow through the fuse on assertion of a programming signal.

8. The integrated circuit of claim 7, further comprising a MOS transistor having a source, a drain, and a gate, the drain conductively connected to the resistor and the source, and the gate connected to the lower voltage rail.

9. The integrated circuit of claim 8, wherein:
the first switch and the second switch are a first matched pair of MOS transistors;
the third switch and the fourth switch are a second matched pair of MOS transistors; and
the fifth switch and the MOS transistor are a third matched pair of MOS transistors.

10. A method of operating a memory cell, comprising:
switching a control signal from a first state to a second state;
closing a first switch and a second switch responsive to the second state, wherein:
the first switch is coupled between a fuse and a first power terminal of a first inverter;
the second switch is coupled between a resistor and a second power terminal of a second inverter; and
the fuse and the resistor are coupled to a first supply rail;
opening a third switch and a fourth switch responsive to the second state, wherein:
the third switch is coupled between an output of the first inverter and a second supply rail;
the fourth switch is coupled between an output of the second inverter and the second supply rail; and
the output of the first inverter is coupled to an input of the second inverter, and the output of the second inverter is coupled to an input of the first inverter; and
reading a value of the output of the first inverter responsive to the second state after the output of the first inverter stabilizes.

11. The method of claim 10, wherein the value of the output of the first inverter is low if the fuse is in an unprogrammed state.

12. The method of claim 10, wherein the output of the first inverter stabilizes in less than 17 ns.

13. The method of claim 10, wherein closing the first switch and the second switch is coincident with opening the third switch and the fourth switch.

14. A method of fabricating an integrated circuit, comprising:
forming a memory cell circuit, including forming first and second cross-coupled inverters over a semiconductor substrate and connecting an output of the first inverter to an input of the second inverter by a first circuit node and connecting an output of the second inverter to an input of the first inverter by a second circuit node;
forming a first switch over the semiconductor substrate and connecting the first switch in a first circuit path from a power rail to a power terminal of the first inverter, the first switch configured to conduct during a first phase of a control signal;
forming a second switch over the semiconductor substrate and connecting the second switch in a second circuit path from the power rail to a power terminal of the second inverter, the second switch configured to conduct during the first phase of the control signal;
forming a third switch over the semiconductor substrate and connecting the third switch between the first circuit node and a reference rail, the third switch configured to conduct during a second phase of the control signal;
forming a fourth switch over the semiconductor substrate and connecting the fourth switch between the second circuit node and the reference rail, the fourth switch configured to conduct during the second phase of the control signal;
forming a resistor over the semiconductor substrate and connecting the resistor between the power rail and the first switch in the first circuit path; and
forming a fuse over the semiconductor substrate and connecting the fuse between the power rail and the second switch in the second circuit path.

15. The method of claim 14, further comprising forming a plurality of the memory cell circuits and arranging the plurality of memory cell circuits in a two-dimensional array.

16. The method of claim 14, further comprising forming a second resistor over the semiconductor substrate and connecting the second resistor in parallel with the fuse between the power rail and the second switch.

17. The method of claim 14, wherein the first inverter has a first NMOS transistor matched to a second NMOS transistor of the second inverter, and the first inverter has a first PMOS transistor matched to a second PMOS transistor of the second inverter.

18. The method of claim 14, wherein the first switch and the second switch are a first matched pair of MOS transistors, and the third switch and the fourth switch are a second matched pair of MOS transistors.

19. The method of claim 14, further comprising:
forming a fifth switch over the semiconductor substrate and connecting the fifth switch between the fuse and the reference rail, the fifth switch configured to connect the fuse to the reference rail on assertion of a programming signal; and
forming a dummy MOS transistor having a source, a drain and a gate, and conductively connecting the drain to the resistor and the source, and connecting the gate to the reference rail.

20. The method of claim 19, wherein:
the first switch and the second switch are a first matched pair of MOS transistors;
the third switch and the fourth switch are a second matched pair of MOS transistors; and
the fifth switch and the dummy MOS transistor are a third matched pair of MOS transistors.
